(19) United States
(12) Patent Application Publication
(10) Pub. No.: US 2006/0096531 A1
(43) Pub. Date: May 11, 2006

(54) Processing device and processing method

(75) Inventors: Tadahiro Ishizaka, Nirasaki-shi (JP); Isao Gunji, Nirasaki-shi (JP); Hiroshi Kannan, Tokyo (JP); Ikuo Sawada, Nirasaki-shi (JP); Yasuhiko Kojima, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/516,311

(22) PCT Filed: Jun. 9, 2003
(86) PCT No.: PCT/JP03/07293

§ 371 Date: Aug. 12, 2005

(30) Foreign Application Priority Data
Jun. 10, 2002 (JP) 2002-169321

(51) Int. Cl. C23C 16/00

(52) U.S. Cl. 118/715; 118/728

(57) ABSTRACT

A chamber having an approximately triangular transverse cross section is provided with a gas supply opening at its one side, and is provided with an exhaust opening at a vertex facing the one side. Further, the gas supply opening is provided with a showerhead-like gas supply section. Based on this configuration, the chamber is structured such that a cross-sectional area of a gas flow passage formed from the gas supply opening to the exhaust opening gradually decreases toward a direction of gas supply. At this time, a thickness of a boundary layer formed on a wall of the chamber becomes substantially constant.

### TECHNICAL FIELD

The present invention relates to a processing apparatus and processing method for applying a predetermined surface treatment to a process target such as a semiconductor wafer or the like.

### BACKGROUND ART

Currently, as a result of advancing miniaturization and high-integration of semiconductor integrated circuits, patterns such as wiring grooves, etc. to be formed in the substrate surface of substrates, etc. are more and more miniaturized. Because of this, in a case where a thin film is to be formed as a base film for the wiring metal, it is demanded that a very thin film be formed uniformly with a good coverage in fine wiring grooves. For this demand, there has recently been developed a method called atomic layer deposition (ALD), as a method capable of forming a film of an atomic layer level even in a fine groove with a good film quality.

ALD is constituted by, for example, the following steps. In the example to be described below, a case will be explained where a base film made of titanium nitride is formed on a surface of a substrate in which wiring patterns (wiring grooves) are formed, by using titanium tetrachloride gas and ammonia gas.

First, a substrate is loaded into a chamber and the interior of the chamber is depressurized to a predetermined degree of vacuum. Sequentially, titanium tetrachloride gas is introduced into the chamber for a predetermined time. As a result, titanium tetrachloride molecules are adsorbed onto the surface of the substrate. After this, the interior of the chamber is subjected to purging by an inert gas, thereby titanium tetrachloride, except titanium tetrachloride molecules adsorbed on the substrate surface and amounting to substantially one layer, is cleared from the chamber.

After purging, ammonia gas is introduced into the chamber for a predetermined time. This causes reaction of the titanium tetrachloride molecules adsorbed on the surface of the substrate with the ammonia molecules, forming a titanium nitride layer that amounts to substantially a monolayer on the surface of the substrate. At this time, multiple layers of ammonia molecules are adsorbed on the titanium nitride layer thusly formed. After this, the interior of the chamber is subjected to purging by an inert gas to clear from the chamber ammonia molecules except ammonia molecules adsorbed on the titanium nitride layer and amounting to substantially one layer.

Then, titanium tetrachloride gas is again introduced into the chamber for a predetermined time. As a result, the adsorbed ammonia molecules and titanium tetrachloride react with each other to form another titanium nitride layer. That is, in this state, titanium nitride layers amounting to substantially two monolayer have been formed.

At this time, multiple layers of titanium tetrachloride molecules are adsorbed on the titanium nitride layer. After this, by subjecting the interior of the chamber to purging by an inert gas, a state appears where titanium tetrachloride amounting to substantially one layer is adsorbed on the titanium nitride layer. After this, the atmosphere in the chamber is switched in such a manner as described above from introduction of ammonia gas, to purging, introduction of titanium tetrachloride gas, purging, . . . , in order to form a predetermined number of atomic layers, i.e., a titanium nitride layer having a predetermined thickness. By switching gas atmosphere in the chamber, for example, several hundred to several thousand times, a titanium nitride film of several nm to several ten nm can be formed. In sum, it is necessary to perform gas atmosphere switching fast in order to achieve a high throughput by using this ALD.

According to the above-described ALD, switching of gas atmosphere in the chamber is performed fast multiple times. In this case, influence of a boundary layer to be formed on an inner surface of the chamber or on a substrate cannot be ignored. In a case where a fluid such as a gas, etc. flows in a space defined by walls etc. (including a substrate surface), a boundary layer is normally formed at a region adjacent to the walls, etc. due to the fluid getting adhered to the walls, etc. Since the velocity field in the boundary layer is composed of only velocity components generally parallel with the walls, etc., mixture of gases hardly occurs and gas motion in the direction of thickness of the boundary layer substantially takes place only by diffusion.

It is generally known that if a fluid equation where a flow field of a perfect fluid is defined is solved, existence of a boundary layer in which influence of a viscosity term on an inertia term cannot be ignored is derived. The thickness δ of the boundary layer measured from the wall is expressed as an equation (1), by employing viscosity coefficient μ of fluid, density ρ of fluid, flow rate U, and distance Δx measured from a predetermined point toward a direction in which the fluid flows. As shown by the equation (1), the thickness δ of the boundary layer is in proportion to the square root of the distance Δx. In other words, as schematically shown in FIG. 7, as the fluid flows farther in an x direction, the thickness δ of the boundary layer increases, resulting in expansion of the boundary layer.
δ=(μΔx/ρU)^{1/2} (1)

The velocity in the x direction is zero in the innermost layer of the boundary layer (the side contacting the wall), whereas the velocity in the x direction is substantially equal to the velocity in the x direction of the entire fluid in the outermost layer of the boundary layer. That is, in the internal layer, the average flow rate in the x direction is smaller than the velocity in the x-direction of the entire fluid. Accordingly, as the boundary layer grows, the velocity (in the x direction) of the entire fluid decreases.

In a case where a gas is supplied into the chamber, a decrease of the flow rate also occurs between the gas supply side (for example, a gas supply opening) and the exhaust side (for example, an exhaust opening), due to a boundary layer formed adjacent to the wall of the chamber. Such a decrease of the flow rate is a serious problem in a case where fast switching of gas atmospheres is required such as a case of ALD described above.

Further, since mixture of gases hardly occurs in the boundary layer as described above, even if the atmospheric gas in the chamber is switched, the gas in the boundary layer is hard to switch. Therefore, growth of the boundary layer increases the time required for sufficiently switching the gas in the entire chamber including the boundary layer, and drops the yield.

There has conventionally been no processing apparatus available that is capable of fast atmosphere switching and has a high yield, and is designed so that such expansion of the boundary layer as described above from the gas supply side to exhaust side can be decreased.

### DISCLOSURE OF INVENTION

In view of the above circumstance, an object of the present invention is to provide a processing apparatus and processing method capable of fast atmosphere switching and having a high yield.

To achieve the above object, a processing apparatus according to a first aspect of the present invention is a processing apparatus for forming a film, comprising:

a chamber;

a gas supply opening which is provided to the chamber for supplying a predetermined gas into the chamber; and

an exhaust opening which is provided to the chamber so as to face the gas supply opening for exhausting the interior of the chamber,

characterized in that the chamber is structured such that a cross section of a flow passage of the gas, the flow passage going from the gas supply opening to the exhaust opening, gradually decreases from the gas supply opening to the exhaust opening.

To achieve the above object, a processing apparatus according to a second aspect of the present invention is characterized by comprising:

a chamber;

a gas supply opening which is provided to the chamber and is connected to gas supply means for alternately supplying plural species of gases into the chamber; and

an exhaust opening which is provided to the chamber so as to face the gas supply opening and is connected to exhaust means for exhausting the interior of the chamber,

the chamber being structured such that a cross section of a flow passage of the gases, the flow passage going from the gas supply opening to the exhaust opening, gradually decreases from the gas supply opening to the exhaust opening.

According to the above configuration, a drop of the flow rate of a gas from the gas supply opening to the exhaust opening is restricted, and the atmosphere in the chamber can therefore be switched fast. Consequently, processing with a high yield becomes available.

The chamber is, for example, structured such that the cross section of the flow passage of the gases decreases in accordance with a distance from the gas supply opening.

It is preferred that the chamber be structured such that a thickness of a boundary layer becomes approximately constant, the boundary layer being formed when the gases are supplied into the chamber, on a wall of the chamber that extends along a direction of flow of the gases.

Further, it is desirable that the chamber be structured such that a thickness of a boundary layer becomes approximately constant, the boundary layer being formed when the gases are supplied into the chamber, on a substrate which is placed in the chamber along a direction of flow of the gases.

That is, for example, by structuring such that the cross section of the flow passage is in reverse proportion to the distance from the gas supply opening, and/or by structuring such that a boundary layer to be formed on a wall of the chamber becomes substantially constant, a decrease in a gas flow rate and in a speed of switching atmosphere, which might be caused by the boundary layer, is restricted. Further, in a case where the thickness of a boundary layer formed on the substrate is constant, uniformity of processing in the principal surface of the substrate is further improved.

To achieve the above object, a processing apparatus according to a third aspect of the present invention is characterized by comprising:

a chamber;

a gas supply opening which is provided to the chamber and is connected to gas supply means for alternately supplying plural species of gases into the chamber; and

an exhaust opening which is provided to the chamber and is connected to exhaust means for exhausting the interior of the chamber,

the chamber having a cross section which has an approximately triangular shape as seen from a direction approximately perpendicular to a direction of supply of the gases, the gas supply opening being provided at substantially entire one side of the cross section, and the exhaust opening being provided at a vertex portion which faces the one side of the cross section.

To achieve the above object, a processing method according to a fourth aspect of the present invention is a method for processing a substrate placed in a chamber by alternately supplying plural species of gases into the chamber from a gas supply opening and switching atmosphere in the chamber, the method characterized by comprising:

a gas supplying step of supplying a predetermined gas into the chamber from the gas supply opening; and

a gas flowing step of causing the predetermined gas supplied in the gas supplying step to flow in the chamber in a manner that the gas has a cross section of flow passage that decreases in accordance with a distance from the gas supply opening.

It is desirable that in the gas flowing step, a boundary layer having an approximately constant thickness be formed on a wall of the chamber and/or the substrate, along a direction of flow of the gas.

According to this method, since a boundary layer having an approximately constant thickness is formed on a wall of the chamber, a flow rate distribution that is uniform along the direction of flow of gas can be obtained and the speed for switching atmosphere can be maintained fast. Further, in a case where a boundary layer having an approximately constant thickness is formed on the substrate, uniformity of processing in the principal surface of the substrate is further improved.

### BRIEF DESCRIPTION OF DRAWINGS

FIG. 1 is a cross section of a processing apparatus according to an embodiment of the present invention, as sectioned from its side;

FIG. 2 is a plan view of the processing apparatus according to the embodiment of the present invention;

FIG. 3 is a diagram exemplarily showing boundary layers to be formed in a case where the processing apparatus according to the embodiment of the present invention is used;

FIG. 4 shows one example of a flowchart of ALD processing;

FIG. 5 is a diagram showing another embodiment of the present invention;

FIG. 6A and FIG. 6B are diagrams showing another embodiment of the present invention; and

FIG. 7 is a diagram exemplarily showing a boundary layer formed adjacent to a wall.

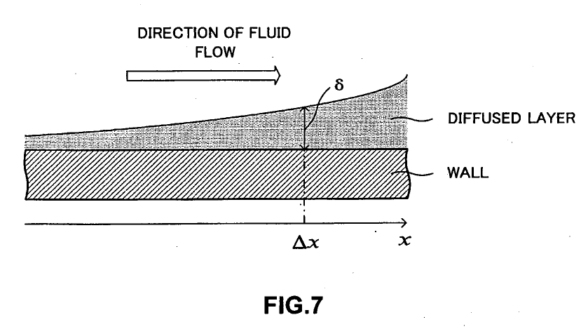

### BEST MODE FOR CARRYING OUT THE INVENTION

A processing apparatus according to an embodiment will be explained with reference to the drawings. In the present embodiment, explanation will be made by employing as an example, a processing apparatus for forming a titanium nitride (TiN) film on a surface of a semiconductor wafer (hereinafter, wafer W) according to a so-called atomic layer deposition (ALD) method, by alternately supplying titanium tetrachloride (TiCl₄) gas and ammonia (NH₃) gas while carrying out purging therebetween using argon (AR) gas.

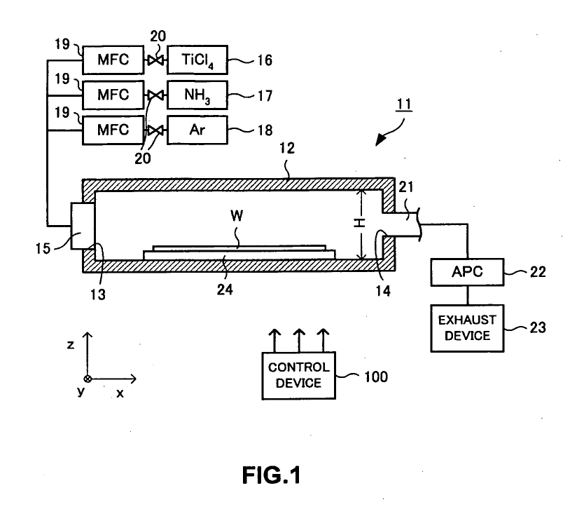

FIG. 1 shows a cross section of a processing apparatus 11 according to the present embodiment, when sectioned from its side. As shown in FIG. 1, the processing apparatus 11 comprises a hollow chamber 12 made of aluminum, stainless steel, etc. The chamber 12 is so structured as to have a vertical cross section having a generally rectangular shape, and to have a predetermined height H in a z-axial direction. A gas supply opening 13 and an exhaust opening 14 are formed at sides of the generally rectangular cross section that face each other in an x-axial direction.

The gas supply opening 13 is provided with a gas supply section 15. The gas supply section 15 is connected to a TiCl₄ gas source 16, an NH₃ source 17, and an Ar source 18 respectively via a mass flow controller 19 and a valve 20.

The exhaust opening 14 has an exhaust duct 21 connected thereto. The exhaust duct 21 is connected to an exhaust device 23 via an automatic pressure controller (APC) 22. The exhaust device 23 exhausts the interior of the chamber 12 to a predetermined degree of vacuum.

A disk-like mount table 24 is provided in the interior of the chamber 12 for mounting a wafer W thereon. The mount table 24 is formed of ceramics such as aluminum nitride or the like. The mount table 24 has an unillustrated embedded heater such as a resistor heat generator or the like.

A control device 100 controls the behaviors of the components of the processing apparatus 11 having the above-described configuration. The control device 100 stores a processing sequence for executing a predetermined processing, and executes the processing to be described later based on this processing sequence. Explanation of the configuration and detailed behaviors of the control device 100 will be omitted herein.

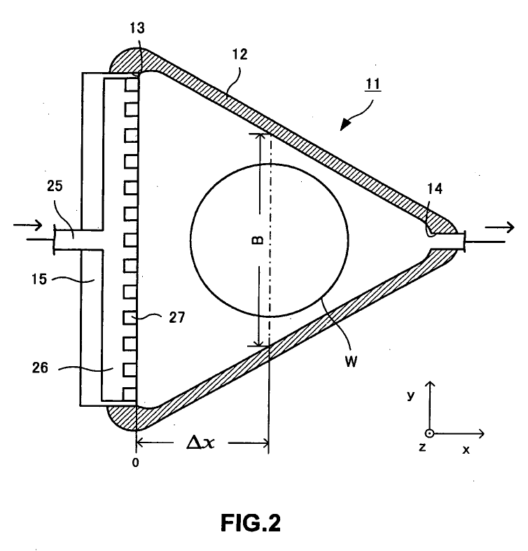

FIG. 2 shows a plan view of the chamber 12. As shown in FIG. 2, the chamber 12 has a generally triangular cross section. The chamber 12 has the gas supply opening 13 at a side of the generally triangular cross section that is parallel with a y-axial direction, and has the exhaust opening 14 at a vertex portion that opposes to this side.

The gas supply opening 13 is formed so as to go across almost the overall of the side that is parallel with the y-axial direction of the chamber 12 shown in FIG. 2, and the gas supply section 15 is provided so as to cover the gas supply opening 13. The gas supply section 15 is connected to a gas supply duct 25 which is connected to the TiCl₄ gas source 16, the NH₃ source 17, and the Ar source 18. The gas supply section 15 has a hollow diffusion section 26 thereinside, and the gas supply duct 25 is connected to the diffusion section 26.

The gas supply section 15 has a plurality of gas supply holes 27 arranged at generally regular intervals in the y-axial direction at portions exposed to the interior of the chamber 12. Each of the gas supply holes 27 is connected to the diffusion section 26. A gas that passes through the gas supply duct 25 is diffused in the diffusion section 26, and is supplied into the interior of the chamber 12 from the plurality of gas supply holes 27 in the x-axial direction. The gas is diffused in the diffusion section 26 and is supplied from the plurality of gas supply holes 27 at supply speeds substantially uniform.

The chamber 12 is structured such that a width B of the chamber 12 in the y-axial direction at a distance Δx measured from the gas supply opening 13 toward the gas supply direction (x-axial direction) is in reverse proportion to Δx. Meanwhile, a cross-sectional area S of the gas flow passage (chamber 12) in the x-axial direction is a product of the height H in the z-axial direction and width B in the y-axial direction of the chamber 12. That is, the chamber 12 is structured such that the cross-sectional area S of the gas flow passage is in reverse proportion to the distance Δx in the gas supply direction while satisfying SΔx=(constant).

A thickness δ of a boundary layer formed on a wall of the chamber 12 at a distance Δx from the gas supply opening 13 is expressed as an equation (2), by employing viscosity coefficient μ, density ρ, and flow rate U of a fluid (gas).
δ=(μΔx/ρU)^{1/2} (2)

The flow rate U is expressed as U=Q/S by employing flow volume Q of a gas and flow passage cross-sectional area S, based on mass balance. An equation (3) is derived by assigning this equation to the equation (2).
δ=(μSΔx/ρQ)^{1/2} (3)

In the equation (3), the viscosity coefficient μ and the density ρ of a predetermined gas component are constant. Further, in a case where the flow volume Q is controlled to be constant, the equation (3) is expressed as follows by employing a constant k.
δ=k(SΔx)^{1/2} (4)

As described above, according to the present embodiment, the chamber 12 is structured such that SΔx=(constant) is satisfied. Consequently, according to the equation (4), boundary layer thickness δ=(constant) is established. Therefore, it is understood that the thickness δ of a boundary layer is constant at any arbitrary position in the x-axial direction.

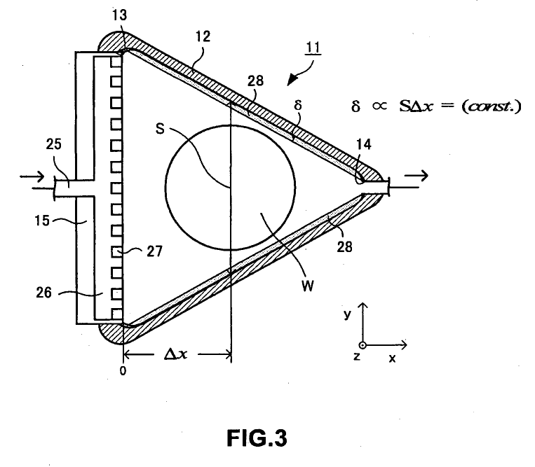

As described above, the cross-sectional area S of the gas flow passage formed in the chamber 12 is in reverse proportion to the distance Δx from the gas supply opening 13, and the thickness δ of a boundary layer formed adjacent to a wall of the chamber 12 therefore becomes substantially constant. FIG. 3 schematically shows the appearance of boundary layers formed in a case where the processing apparatus 11 is used. As shown in FIG. 3, from the supply side to the exhaust side, i.e., as Δx increases, the flow passage cross-sectional area S (i.e., width B) decreases gradually, whereas the thickness δ of the boundary layers 28 is constant. The flow passage cross-sectional area S represents the area of a surface that is generally perpendicular to the direction of gas flow in a space through which a gas flowing in the chamber 12 passes.

As described above, the chamber 12 is structured such that its flow passage cross-sectional area decreases gradually and the thickness δ of the boundary layers 28 is substantially constant. This restricts decrease in the flow rate (in the x-axial direction) of a gas from the gas supply opening 13 to the exhaust opening 14.

Further, as described above, even in a case where a gas to be introduced into the chamber 12 is switched to another one, the gas in the boundary layers 28 is difficult to switch. According to the present embodiment, since such a growth of the boundary layers 28 as described above is restricted, it is possible to switch gas atmospheres in the chamber 12 in a short time. The capability of fast atmosphere switching makes it possible to obtain a high throughput and a high yield.

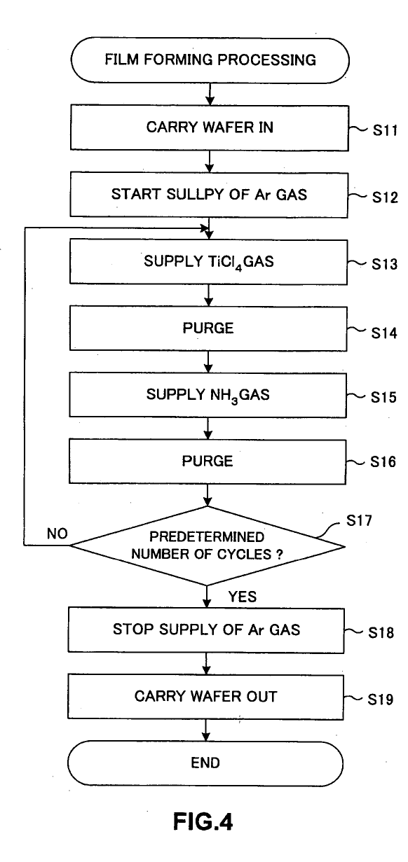

Next, a method of forming a TiN film on the surface of a wafer W using the processing apparatus 11 having the above-described configuration will be explained with reference to FIG. 4. FIG. 4 is a flowchart showing a method of forming a TiN film according to the present embodiment. The flowchart shown in FIG. 4 is one example of processing, and the processing is not limited to the procedures shown in the flowchart as long as a similar resulting product is obtained.

First, an unillustrated carrier arm, for example, is operated to carry a wafer W into the chamber 12 and mount it on the mount table 24 (step S11). Then, the heater in the mount table 24 is controlled so that the wafer W is heated to a predetermined temperature, for example, 450° C. Simultaneously, Ar gas is supplied into the chamber 12 (step S12). The Ar gas is supplied with its flow volume controlled to 200 sccm. At this time, the pressure in the chamber 12 is maintained at, for example, 400 Pa (3 Torr). The Ar gas is let to flow in the chamber 12 all the time during the processing steps to be described below.

Next, TiCl₄ gas is supplied into the chamber 12 for a predetermined time, for example, for 0.5 second (step S13). The TiCl₄ gas is supplied with its flow volume controlled to 30 sccm. At this time, TiCl₄ molecules are adsorbed onto the surface of the wafer W.

After a predetermined time passes, the supply of the TiCl₄ gas is stopped. The Ar gas is still flowing in this state, and the interior of the chamber 12 is purged by the Ar gas (step S14). At this time, the TiCl₄ gas (molecules), except TiCl₄ molecules that have been adsorbed on the surface of the wafer W and amount to substantially a monolayer, is exhausted and cleared from the chamber 12.

Next, after purging is carried out for a predetermined time, for example, for 0.5 second, NH₃ gas is supplied into the chamber for a predetermined time, for example, 0.5 second (step S15). The NH₃ gas is supplied while controlled to, for example, 50 sccm.

At this time, the NH₃ molecules react with the TiCl₄ molecules adsorbed on the surface of the wafer W, forming a TiN layer that amounts to substantially a monolayer. NH₃ molecules are further adsorbed onto the formed TiN layer.

After a predetermined time passes, the NH₃ gas is stopped. The Ar gas is still flowing in this state, and the interior of the chamber 12 is purged by the Ar gas (step S16). At this time, except the NH₃ molecules that have been adsorbed on the TiN layer and amount to substantially one layer, the NH₃ molecules in the chamber 12 are exhausted and removed.

After purging is carried out for a predetermined time, for example, for 0.5 second, the flow returns to step S13 to supply the TiCl₄ gas into the chamber 12. At this time, the TiCl₄ molecules react with the NH₃ molecules on the TiN layer, forming a new TiN layer that amounts to substantially a monolayer. TiCl₄ molecules are further adsorbed onto this TiN layer.

After the TiCl₄ gas is supplied, purging by Ar gas is carried out (step S14). As a result, the TiCl₄ molecules except the TiCl₄ molecules that have been adsorbed on the TiN layer and amount to substantially one atomic layer, are exhausted and removed from the chamber 12.

Next, the NH₃ gas is supplied into the chamber 12 (step S15). As a result, the NH₃ molecules and the TiCl₄ molecules adsorbed on the TiN layer react with each other, forming a new TiN layer. NH₃ molecules are further adsorbed onto this TiN layer.

After the NH₃ gas is supplied, purging by Ar gas is carried out (step S16). Due to this, the NH₃ molecules, except the NH₃ molecules that have been adsorbed on the TiN layer and amount to substantially a monolayer, are exhausted and cleared from the chamber 12.

Thereafter, the processes of step S13 through step S16 are repeated to laminate TiN layers on the basis of substantially a monolayer by layer. A TiN film having a predetermined thickness is formed by repeating the above processes a predetermined number of times. The control device 100 memorizes the number of repeat times required to form a TiN layer having the predetermined thickness.

In step S17, the control device 100 determines whether or not the processes of step S13 through step S16 are repeated the required number of times described above. In a case where it is determined that the predetermined number of times is not reached (step S17: NO), the flow returns to step S13 to repeat the above-described processes. In a case where it is determined that the predetermined number of times is reached (step S17: YES), the supply of the Ar gas is stopped (step S18). Then, the wafer W is carried to the outside of the chamber 12 by, for example, a carrier arm (step S19). Thus, the film forming processing is completed.

As explained above, the processing apparatus 11 of the present embodiment is formed such that the cross-sectional area of the gas flow passage gradually decreases from the supply side to the exhaust side so that the thickness of the boundary layers 28 to be formed on the walls thereinside becomes substantially constant. In other words, the chamber 12 of the processing apparatus 11 is structured such that its flow passage cross-sectional area is in reverse proportion to the distance from the gas supply opening 13. This restricts expansion of the boundary layers 28 at the exhaust side.

Since expansion of the boundary layers 28 is restricted as described above, it is possible to switch gas atmospheres at a high speed. Further, since the thickness of the boundary layers 28 formed adjacent to the walls of the chamber 12 is substantially reduced compared to the case of a conventional processing apparatus, atmosphere switching becomes easy and a faster atmosphere switching in a shorter time becomes available. As a result of these, a high yield can be obtained.

The present invention is not limited to the above-described embodiment, but may be modified and applied in various manners. A modification of the above-described embodiment that can be applied to the present invention will be explained below.

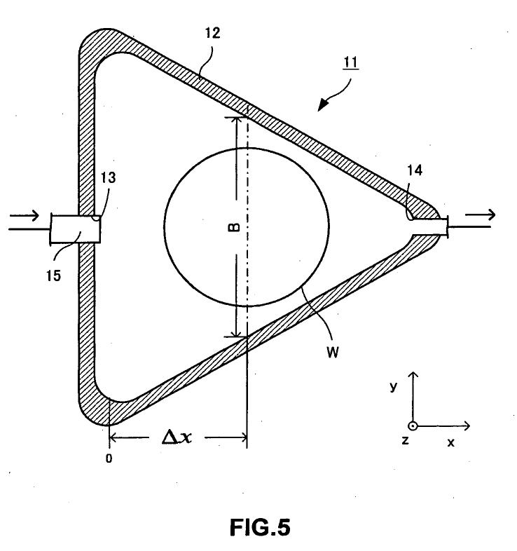

In the above-described embodiment, the gas supply opening 13 is provided with the gas supply section 15 having the diffusion section 26. However, the gas supply section 15 may have a nozzle structure as shown in FIG. 5. The configuration shown in FIG. 5 causes a gas, which is supplied from the gas supply section 15 having the nozzle structure, to be also diffused in the chamber 12 immediately after the gas is supplied into the chamber 12, thereby making it possible to realize a flow of gas that resembles a case where the a gas is supplied from the entire wall of the chamber 12 having the gas supply opening 13 and to obtain a similar effect.

In the above-described embodiment, the wafer W is heated by the heater embedded in the mount table 24. However, the wafer W may be heated by an infrared lamp or the like that is provided on the internal wall of the chamber.

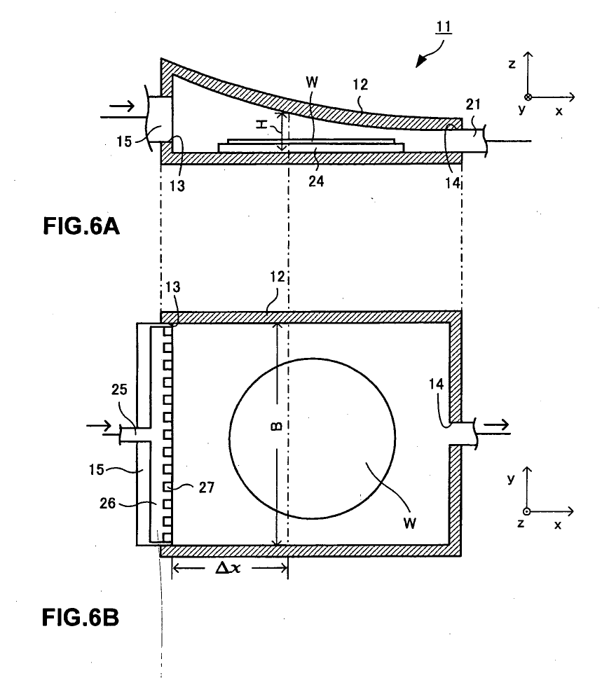

In the above-described embodiment, of the parameters constituting the flow passage cross-sectional area S (=HB), the width B in the y-axial direction is varied in accordance with the distance Δx. However, the width B may be maintained constant while as shown in, for example, FIG. 6A and FIG. 6B, the height H in the z-axial direction is varied. FIG. 6A shows a cross section of the chamber 12 when sectioned from its side, and FIG. 6B shows a plan view thereof.

As shown in FIG. 6B, the chamber 12 has a cross section that is rectangular as seen from the z-axial direction, and its width B in the y-axial direction is constant relative to the x-axial direction. Further, as shown in FIG. 6A, the chamber 12 has a cross section having an approximately trapezoidal shape whose upper edge is formed like an arc as seen from the y-axial direction. In other words, the chamber 12 is structured such that the height H in the z-axial direction gradually decreases toward the gas supply direction (x-axial direction). Because of this, the cross-sectional area S of the gas flow passage gradually decreases toward the exhaust side and is in reverse proportion to the increase of Δx. Accordingly, effects similar to those in the above-described embodiment can be obtained and the thickness δ of the boundary layers can be maintained constant. In this case, a boundary layer to be formed on the wafer W is maintained substantially constant. Therefore, the in-plane uniformity of the thickness of the film to be formed on the wafer W can further be improved.

Further, unlike the above case where either one of the height H and width B is varied along the x-axial direction, the both may be such that are expressed as functions that are varied relative to the x-axial direction while satisfying S=H(x)×B(x)=(constant).

Further, the shape of the chamber 12 may not necessarily be so structured as to strictly satisfy the above equation, but may be formed such that at least the thickness δ of a boundary layer becomes substantially constant.

In the above-described embodiment, only the boundary layers 28 formed on the walls of the chamber 12 are taken into consideration. However, the shape of the chamber 12 may be determined by performing a more detailed simulation using a computing method such as, for example, finite element method or the like, in consideration of the side surfaces of the mount table, the surface of the wafer W, etc.

In the above-described embodiment, a TiN film is formed on the surface of the wafer W a monolayer by monolayer by using TiCl₄ and NH₃. However, the TiN film to be formed on the surface of the wafer W needs only to be a laminated film made of layers having a thickness that corresponds to the level of an atomic layer, and the thickness of one layer is not limited to a monolayer.

In the above-described embodiment a TiN film is formed on the surface of the wafer W by using TiCl₄ and NH₃. However, the substances to be used for film formation and the kinds of films to be formed are not limited to these. In addition to a TiN film, other metal films such as Al₂O₃, ZrO₂, TaN, SiO₂, SiN, SiON, WN, WSi, RuO₂, etc. may be formed. In this case, as to the kinds of gases to be used, any one kind of TaBr₅, Ta(OC₂H₅)₅, SiCl₄, SiH₄, Si₂H₆, SiH₂Cl₂, WF₆, etc. may be used instead of TiCl₄, and any one kind of N₂, O₂, O₃, NO, N₂O, N₂O₃, N₂O₅, etc. may be used instead of NH₃.

Further, the purging gas needs only to be an inert gas, and is not therefore limited to Ar, but nitrogen, neon, etc. may be used.

The processing apparatus 11 of the present invention may be connected inline to a processing apparatus for performing other processings such as annealing, etc., or may be formed in a cluster.

A person with ordinary skill in the art would apply various modifications, etc. to the above-described embodiment without departing from the sprit and scope of the present invention. The above-described embodiment is intended for illustration, and not intended to restrict the scope of the present invention. Accordingly, the scope of the present invention should be determined along the entire scope of equivalent in which the claims defined below are entitled to protection.

This application is based on Japanese Patent Application No. 2002-169321 (filed on Jun. 10, 2002) and including specification, claims, drawings and summary thereof. The disclosure of the above Japanese Patent Application is incorporated herein by reference in its entirety.

### INDUSTRIAL APPLICABILITY

The present invention can be applied not only to a film forming processing but also to all processings such as etching processing, etc. in which plural kinds of gases are used and process atmospheres need to be switched fast.

Further, the present invention can be applied not only to a semiconductor wafer, but also to a substrate for a liquid crystal display device.

As explained above, according to the present invention, there are provided a processing apparatus and processing method capable of fast atmosphere switching and having a high yield.

1-8. (canceled)

9. A processing apparatus for forming a film, comprising:
a chamber;
a gas supply section provided to said chamber for supplying a predetermined gas into said chamber; and
an exhaust opening provided to said chamber so as to face said gas supply section and connected to exhaust means for exhausting an interior of said chamber,
wherein said chamber is structured such that a cross section of a flow passage of said gas, said flow passage going from said gas supply section to said exhaust opening, gradually decreases from said gas supply section to said exhaust opening.

10. A processing apparatus comprising
a chamber;
a gas supply opening provided to said chamber and connected to gas supply means for alternately supplying plural species of gases into said chamber; and
an exhaust opening provided to said chamber so as to face said gas supply opening and connected to exhaust means for exhausting an interior of said chamber,
said chamber being structured such that a cross section of a flow passage of said gases, said flow passage going from said gas supply opening to said exhaust opening, gradually decreases from said gas supply opening to said exhaust opening.

11. The processing apparatus according to claim 10,
wherein said chamber is structured such that said cross section of said flow passage of said gases decreases in accordance with a distance from said gas supply opening.

12. The processing apparatus according to claim 10,
wherein said chamber is structured such that a thickness of a boundary layer is approximately constant, said boundary layer being formed when said gases are supplied into said chamber, on a wall of said chamber that extends along a direction of flow of said gases.

13. The processing apparatus according to claim 10,
wherein said chamber is structured such that a thickness of a boundary layer is approximately constant, said boundary layer being formed when said gases are supplied into said chamber, on a substrate placed in said chamber approximately parallel with a direction of flow of said gases.

14. A processing apparatus comprising:
a chamber;
a gas supply opening provided to said chamber and connected to gas supply means for alternately supplying plural species of gases into said chamber; and
an exhaust opening provided to said chamber and connected to exhaust means for exhausting an interior of said chamber,
said chamber having a cross section that has an approximately triangular shape as seen from a direction approximately perpendicular to a direction of supply of said gases, said gas supply opening being provided at substantially an entire one side of said cross section, and said exhaust opening being provided at a vertex portion that faces said one side of said cross section.

15. A method for processing a substrate placed in a chamber by alternately supplying plural species of gases into said chamber from a gas supply opening and switching atmosphere in said chamber, said method comprising:
supplying a predetermined gas into said chamber from said gas supply opening; and
causing said predetermined gas supplied in said gas supplying to flow in said chamber in a manner that said gas has a cross section of flow passage that decreases in accordance with a distance from said gas supply opening.

16. The processing method according to claim 15,
wherein in said gas flow, a boundary layer having an approximately constant thickness is formed on a wall of at least one of said chamber and said substrate, along a direction of flow of said gas.

17. The processing apparatus according to claim 9,
wherein said gas supply section includes a plurality of gas supply holes arranged approximately parallel with a direction of width of said chamber.

18. The processing apparatus according to claim 17,
wherein said gas supply section includes a gas diffusion section connected to said gas supply holes.

19. The processing apparatus according to claim 9,
wherein said cross section of said flow passage is formed so as to be in reverse proportion to a distance from said gas supply section.

20. The processing apparatus according to claim 19,
wherein said cross section of said flow passage is formed by a width of said chamber that is approximately constant and a height of said chamber that decreases along a direction of flow of said gas.

21. The processing apparatus according to claim 9,
wherein a boundary layer having an approximately constant thickness is formed on a inner wall of said chamber along a direction of flow of said gas.
